(19) United States
(12) Patent Application Publication
(10) Pub. No.: US 2011/0206144 A1
(43) Pub. Date: Aug. 25, 2011

(54) RECEIVER AND TRANSMISSION/RECEPTION SYSTEM

(75) Inventors: Akira YAMAMOTO, Osaka (JP); Kouji Okamoto, Osaka (JP); Yoshinori Shirakawa, Osaka (JP)

(73) Assignee: PANASONIC CORPORATION, Osaka (JP)

(21) Appl. No.: 13/101,679

(22) Filed: May 5, 2011

Related U.S. Application Data
(63) Continuation-in-part of application No. PCT/JP2010/000908, filed on Feb. 15, 2010.

(30) Foreign Application Priority Data
Oct. 19, 2009 (JP) 2009-240781

(51) Int. Cl. H03K 9/00; H04L 27/00

(52) U.S. Cl. 375/259; 375/316; 375/345; 375/324

(57) ABSTRACT

In a wireless receiver, a “variance” of an intermediate output signal of a demodulation section is calculated by a variance calculation section, and the calculated variance is used as a signal quality indicator which indicates the degree of goodness of a receiving condition. For example, when the “variance” is small, a gain of a low-noise amplifier is reduced, or an operation clock frequency of a baseband oscillator is reduced, etc. Thus, when the receiving condition indicated by the indicator is good and sufficient performance is ensured, the performance can be slightly lowered to reduce power consumption. The “variance” is a compact indicator which can be calculated using a simple operation, and is used as a new signal quality indicator.

### CROSS-REFERENCE TO RELATED APPLICATION

This is a continuation of PCT International Application PCT/JP2010/000908 filed on Feb. 15, 2010, which claims priority to Japanese Patent Application No. 2009-240781 filed on Oct. 19, 2009. The disclosures of these applications including the specifications, the drawings, and the claims are hereby incorporated by reference in their entirety.

### BACKGROUND

The present disclosure relates to optimization of performance and power consumption in a receiver of a wireless transmission/reception system.

In recent years, wireless communication using a millimeter waveband (60 GHz band) has attracted attentions. Major reasons for this are that high-speed data transmission at a rate over 1 Gbps can be realized by using a wide band requiring no license, and that systems for wireless communication can be fabricated using CMOS devices, etc.

There has been a growing trend toward providing portable terminals with millimeter wave radio systems, and accordingly, reduction in power consumption has become a major challenge.

In a wireless communication transmission/reception system, when it is desired to optimize the performance and power consumption thereof together, a method in which, when the channel quality is good and more than sufficient performance can be ensured, the performances of a transmitter or a receiver are slightly degraded to reduce power consumption can be used. The channel quality herein means not only the quality of a communication path from a transmission antenna to a reception antenna but also the quality of each block in the transmitter and the receiver.

As an indicator of the channel quality, there is a bit error rate (bER), but it is actually difficult to obtain bER. A reason for this is that it is not easy to obtain a correct bit sequence serving as a basis for determining bit errors. Also, to obtain highly reliable bER which can be actually used as an indicator, an enormous number of bits are required. For example, to obtain a value of bER=10⁻³ with high reliability, at least one hundred thousand bits are required. This is another reason why it is difficult to obtain bER.

A physical layer of the receiver is comprised of many blocks such as a bandpass filter (BPF), a low-noise amplifier (LNA), a variable gain amplifier (VGA), and a DC offset controller, etc. Those blocks have to optimally control parameters according to a receiving condition. For example, parameters such as the gain of a LNA, the gain of a VGA, and control of a DC offset controller, etc., are optimized based on an output value of an analog-to-digital converter (ADC).

An optimal state of a physical layer should be obtained based on bER as a final result, not an output of the ADC in the course of reception. Parameters should be optimized so that bER is minimal. However, as described above, calculation of bER is difficult, and thus, calculation of true optimal parameters based on bER is very difficult.

Thus, conventionally, for example, in Japanese Patent Publication No. 2006-229733, the gain of a LNA of a receiver is controlled using, instead of bER, a modulation error rate (MER) as a channel quality indicator and, when the channel quality is good, i.e., when the receiving condition is good, the gain of the LNA is reduced to lower power, thereby reducing power consumption. An equation for calculating MER is shown below.

$$MER = 10 \times {log}_{10} \{ \frac{{\sum }_{j = 1}^{N} ( {I}_{j}^{2} + {Q}_{j}^{2} )}{{\sum }_{j = 1}^{N} ( δ {I}_{j}^{2} + δ {Q}_{j}^{2} )} \} [ dB ] \qquad [ Equation 1 ]$$

### SUMMARY

The indicator MER described in Japanese Patent Publication No. 2006-229733 is a compact indicator, as compared to bER. However, as understood from Equation 1 shown above, division and log operation are complicated. This causes increase in the circuit area and power consumption, and it is a challenge to solve this problem. Japanese Patent Publication No. 2006-229733 only describes the control of LNA.

It is therefore an objective of the present disclosure to propose a new indicator which is more compact than the indicator conventionally used for indicating a receiving condition in a receiver in a wireless transmission/reception system to more finely control various blocks of which the receiver is comprised.

To achieve the above-described objective, a receiver according to the present disclosure, which includes a demodulation section configured to demodulate a received signal, includes a variance calculation section configured to calculate a variance of an intermediate output signal of the demodulation section as an indicator for signal quality.

According to the present disclosure, the receiver may be configured so that in the receiver, the demodulation section includes an analog/digital converter, and the variance calculation section calculates a variance of a signal in a subsequent stage of the analog/digital converter.

According to the present disclosure, the receiver may configured so that in the receiver, the variance calculation section calculates the variance σ based on an equation:

$$σ = \frac{1}{N - 1} {\sum }_{j = 1}^{N} {( {x}_{j} - \overline{x} )}^{2} \\ ( \overline{x} is a mean value of x ) \qquad [ Equation 2 ]$$

where a value of a signal at a time j is xj.

According to the present disclosure, the receiver may further include a parameter control section configured to receive the variance calculated by the variance calculation section and control a parameter of a block provided in the demodulation section so that a value of the variance is good.

According to the present disclosure, the receiver may be configured so that in the receiver, the block provided in the demodulation section is a low-noise amplifier configured to amplify the received signal, and the parameter control section controls a gain of the low-noise amplifier.

According to the present disclosure, the receiver may be configured so that in the receiver, the block provided in the demodulation section is a baseband oscillator, and the parameter control section controls an oscillation frequency of the baseband oscillator.

According to the present disclosure, the receiver may be configured so that in the receiver, the block provided in the demodulation section is an analog/digital converter, and the parameter control section controls an output bit width of the analog/digital converter.

According to the present disclosure, the receiver may be configured so that in the receiver, the block provided in the demodulation section is a digital arithmetic block, and the parameter control section controls operation accuracy of the digital arithmetic block.

According to the present disclosure, the receiver may be configured so that in the receiver, the block provided in the demodulation section includes a bandpass filter, a RF oscillator, an automatic gain controller, a DC offset canceller, a symbol synchronizer, or a carrier offset corrector.

According to the present disclosure, the receiver may be configured so that in the receiver, the received signal includes binary data mapped on an I/Q plane, and the block provided in the demodulation section includes a 90 degree phase section or an IQ imbalance corrector.

According to the present disclosure, the receiver may be configured so that in the receiver, in the demodulation section, an error correction block is provided, the parameter control section controls the parameter of the block provided in the demodulation section so that the variance calculated by the variance calculation section is close to a value corresponding to an error correction limit of the error correction block.

A transmission/reception system according to the present disclosure includes the above-described receiver, and a transmitter configured to transmit a transmission signal to the receiver.

According to the present disclosure, the transmission/reception system may be configured so that in the transmission/reception system, the receiver transmits the variance calculated by the variance calculation section to the transmitter, and the transmitter controls transmission power of the transmission signal based on the variance transmitted from the receiver.

According to the present disclosure, the transmission/reception system may be configured so that in the transmission/reception system, the transmission signal is a signal in a millimeter wave band.

Based on the foregoing, according to the present disclosure, the “variance” of the intermediate output signal of the demodulation section is used as an indicator for signal quality. The “variance” has a strong correlation with bER, and is a compact indicator which does not require, as opposed to a conventional indicator MER, division or logarithmic operation. Thus, if various blocks of the receiver and the transmission/reception system are finely controlled so that the value of the “variance” is small, the performance and power consumption of the receiver and the transmission/reception system can be optimized.

As described above, according to the present disclosure, the “variance” which is a compact indicator having a strong correlation with bER and does not require, as opposed to a conventional indicator MER, division or logarithmic operation is used as an indicator. Thus, the performance and power consumption of the receiver and the transmission/reception system can be optimized by finely controlling various blocks of a receiver and a transmission/reception system so that the indicator is small.

### BRIEF DESCRIPTION OF THE DRAWINGS

FIG. 1 is a diagram schematically illustrating a configuration of a receiving physical layer serving as a receiver according to a first embodiment of the present disclosure.

FIG. 2 is a diagram schematically illustrating a configuration of a transmitting physical layer serving as a transmitter according to the first embodiment.

FIG. 3A is a graph showing ideal signal points for outputs of an I/Q demapping section of the receiver of the first embodiment. FIG. 3B is a graph showing the ideal signal points in the form of histogram. FIG. 3C is a graph showing actual output ranges of the output signals. FIG. 3D is a graph showing the actual output ranges using only values in an I-axis direction in the form of histogram.

FIGS. 4A-4D are graphs showing 1-bit binary data mapped on an I/Q plane by π/2-BPSK modulation performed by an I/Q mapping section of the transmitter of the first embodiment. FIG. 4A is a graph showing the binary data mapped on an I/Q plane when time t=4n, FIG. 4B is a graph showing the binary data mapped on an I/Q plane when time t=4n+1, FIG. 4C is a graph showing the binary data mapped on an I/Q plane when time t=4n+2, and FIG. 4D is a graph showing the binary data mapped on an I/Q plane when time t=4n+3.

FIGS. 5A-5D are graphs showing likelihood points for the binary data converted by an I/Q demapping section of the receiver of the first embodiment from the signal points mapped by π/2-BPSK modulation. FIG. 5A is a graph showing the likelihood points when time t=4n, FIG. 5B is a graph showing the likelihood points when time t=4n+1, FIG. 5C is a graph showing the likelihood points when time t=4n+2, and FIG. 5D is a graph showing the likelihood points when time t=4n+3.

FIG. 6 is a diagram illustrating an entire configuration of a transmission/reception system according to a fifth embodiment of the present disclosure.

### DETAILED DESCRIPTION

Embodiments of the present disclosure will be hereinafter described with reference to the accompanying drawings.

### First Embodiment

First, a transmission system and a reception system of a physical layer (PHY) of a millimeter-wave communication system will be briefly described.

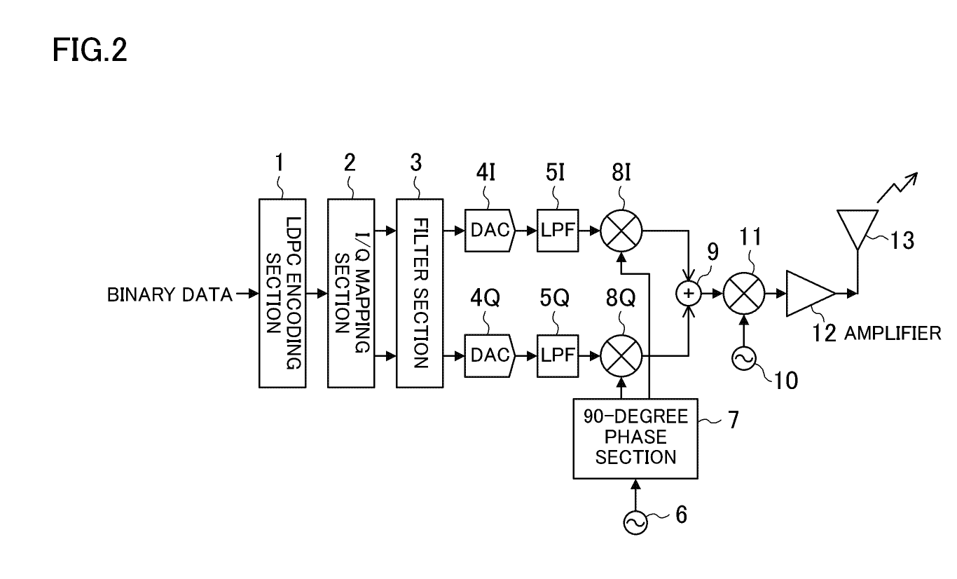

The physical layer of the transmission system of the millimeter-wave communication system will be briefly described with reference to FIG. 2.

In a transmitter of FIG. 2, a signal to be input is binary data {0, 1}. A low-density parity check (LDPC) encoding section 1 is a block for error-correcting coding. When binary data transmitted through a communication path (a channel) is affected by noise, etc., in the course of reception by a receiver and is received by the receiver incorrectly, the transmission data and the reception data are not matched. The LDPC encoding section 1 performs error-correcting coding in advance in a stage prior to decoding, so that, even when reception data is different from the transmission data, errors are corrected and the reception data is matched with transmission data. There are various types of error-correcting coding, such as Reed-Solomon coding, etc. In this embodiment, LDPC is described as one example, but the present disclosure is not limited to LDPC.

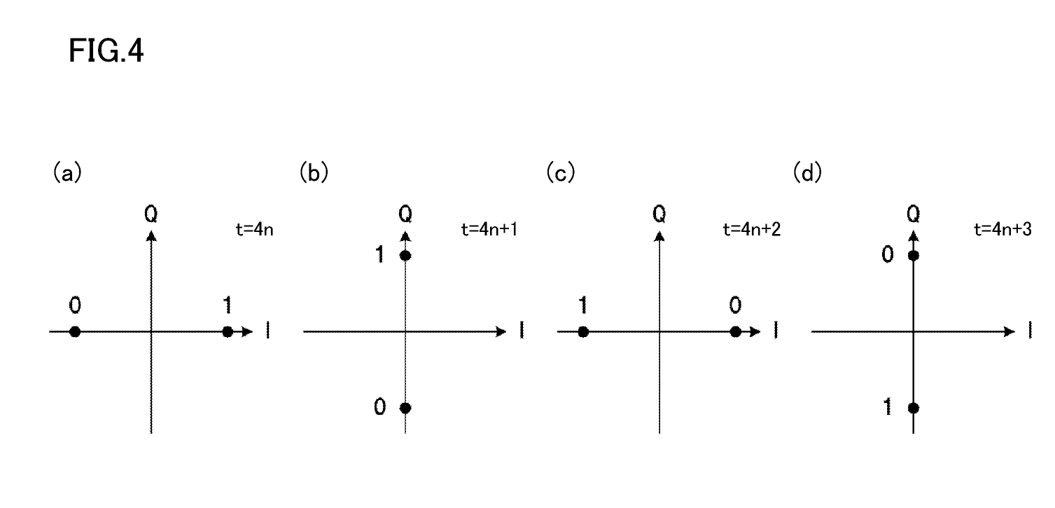

An I/Q mapping section 2 performs mapping of binary data on an I/Q plane (i.e., a plane including in-phase components and quadrature components). There are various types of mapping, and in this case, π/2-binary phase shift keying (BPSK) modulation will be described as an example. In π/2-BPSK modulation, 1 bit binary data is mapped on a signal point on the I/Q plane, and the binary data is rotated by π/2 per bit. A specific example is shown in FIGS. 4A-4D. The I/Q mapping section 2 has two outputs, i.e., an in-phase (I) channel output and a quadrature (Q) channel output. Each of the outputs is a rectangular wave of a ternary signal {−1, 0, 1}.

A filter section 3 is a digital filter configured to reduce intersymbol interference (ISI) while attenuating high-frequency components of a rectangular wave signal.

Digital-to-analog converters (DACs) 4I and 4Q convert digital signals of I channel and Q channel into respective analog signals.

Low-pass filters 5I and 5Q are filters configured to attenuate high-frequency components of the analog signals as outputs of the DACs 4I and 4Q separately for the I channel and the Q channel.

A baseband (BB) oscillator 6 is an oscillator which oscillates at a baseband. In this case, for example, the oscillation frequency fsym of the BB oscillator 6 is 1.76 GHz. A clock for driving digital sections such as the LDPC encoding section 1, the I/Q mapping section 2, and the filter section 3, etc., and a sampling clock of the DACs 4I and 4Q are synchronized with an output signal of the BB oscillator 6.

A 90 degree phase section 7 generates two signals of which phases are 90 degrees different from each other. When an oscillation signal of 1.76 GHz from the BB oscillator 6 is input to the 90 degree phase section 7, the 90 degree phase section 7 outputs two signals, i.e., a cosine wave signal (cos 2πfsymt) of 1.76 GHz and a sine wave signal (−sin 2πfsymt) of 1.76 GHz.

A mixer 8I of the I channel in the baseband multiplies an output of a LPF 5I of the I channel by the 1.76 GHz cosine wave signal of the 90 degree phase section 7. A mixer 8Q of the Q channel in the baseband multiplies an output of a LPF 5Q of the Q channel by the 1.76 GHz sine wave of the 90-degree phase section 7. Thereafter, an adder 9 adds outputs of the mixers 8I and 8Q of the I channel and the Q channel together.

A radio frequency (RF) oscillator 10 is an oscillator which oscillates at the RF band, and the oscillation frequency fc of the RF oscillator 10 is, for example, 60 GHz in a millimeter waveband.

A mixer 11 in the RF band multiplies an output of the adder 9 by an output of the RF oscillator 10 in the RF band. Since the output of the adder 9 is a signal in the baseband and the signal is carried on an output signal of the RF oscillator 10, the output signal of the RF oscillator 10 is called carrier wave.

An amplifier 12 amplifies an output of the mixer 11 in the RF band. An antenna 13 sends an output of the amplifier 12 as a radio wave in the 60 GHz band into the air.

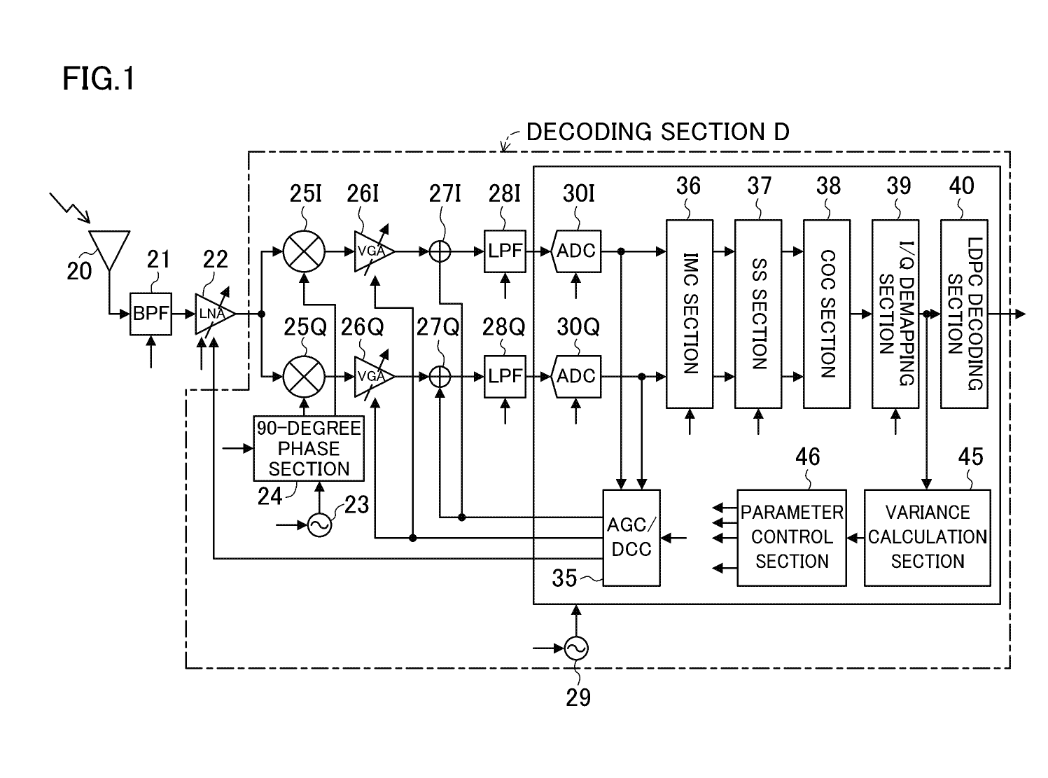

Subsequently, a physical layer of the receiving system of the millimeter wave communication system will be described with reference to FIG. 1.

In the receiver of FIG. 1, an antenna 20 receives a radio wave in a millimeter waveband, i.e., for example, the 60 GHz band.

A bandpass filter (BPF) 21 filters signals having frequencies in other bands than the band of the radio wave received by the antenna 20.

A low-noise amplifier (LNA) 22 amplifies an output signal of the BPF 21. When a received signal at the antenna 20 is small, data cannot be reproduced unless a gain is increased. However, when the gain is increased, the power consumption increases. Therefore, depending on a receiving condition, an optimal point for the gain, the signal reproduction quality, and the power consumption varies.

In a demodulation section D in a subsequent stage of the LNA 22, a RF oscillator 23 generates a signal of 60 GHz, and a 90 degree phase section 24 generates two signals of 60 GHz of which phases are 90 degrees different from each other. For example, the 90-degree phase section 24 generates two signals of 60 GHz, i.e., a signal cos 2πfct for the I channel and a signal −sin 2πfct for the Q channel.

A mixer 25I of the I channel in the RF band multiplies an output of the LNA 22 by an I channel output of the 90 degree phase section. Thereafter, high frequency components are eliminated, and thus, an I channel baseband signal can be obtained. Also, a mixer 25Q of the Q channel in the RF band multiplies an output of the LNA 22 by an Q channel output of the 90 degree phase section. Thereafter, high frequency components are eliminated, and thus, a Q channel baseband signal can be obtained.

Outputs of the mixers 25I and 25Q of the I and Q channels are subjected to amplitude adjustment by variable gain amplifiers (VGAs) 26I and 26Q and DC offset adjustment by DC offset controllers 27I and 27Q to be within respective input ranges of analog-to-digital converters (ADCs) 30I and 30Q, which will be described later.

Low-pass filters (LPFs) 28I and 28Q are respective prefilters of the ADCs 30I and 30Q, and each have the anti-aliasing function.

A baseband (BB) oscillator 29 is an oscillator which oscillates at the baseband, and generates a clock having a frequency higher than 1.76 GHz. The clock serves as a sampling block for the ADCs 30I and 30Q, and also serves as a clock driving digital blocks such as an AGC/DCC 35, an IMC section 36, a SS section 37, a COC section 38, an IQ demapping section 39, and a LDPC decoding section 40, etc. In this example, an output of the BB oscillator 29 of the receiver and an output of the BB oscillator 6 of the transmitter are not synchronized. After oversampling, the outputs thereof are digitally synchronized.

The ADCs 30I and 30Q are blocks for converting an analog wave to a digital signal. Timings of samplings correspond to rising edges of an output clock of the BB oscillator 29.

The AGC/DCC 35 includes an automatic gain controller and a direct current offset canceller. Since there are lower and upper limits for signals which the ADCs 30I and 30Q of the I and Q channels can receive. The AGC/DCC 35 is a block for controlling a signal so that the signal does not exceed or lower the limits. When an amplitude of an input signal is too small, the signal is included into quantization noise of the ADCs 30I and 30Q. Therefore, when an amplitude of an input signal is too small, the AGC/DCC 35 controls the signal so that the signal is properly between the lower and upper limits. The AGC/DCC 35 determines a control value by monitoring output signals of the ADCs 30I and 30Q. For example, when it is likely that each of input signals of the ADCs 30I and 30Q exceeds the upper limit of the input range of the ADCs, the gains of the LNA 22 and the VGAs 26I and 26Q are reduced. In contrast, when each of the input signals to the ADCs is too small, the gains of the LNA and the VGAs are increased. When each of center values of the input signals of the ADC 30I or 30Q is off from the center values of the input ranges of the ADCs, the center values of the input signals of the ADC 30I or 30Q are increased or reduced by a DC offset controller, thereby adjusting the center values of the input signals.

In FIG. 1, an IQ imbalance correction (IMC) section (a digital arithmetic block) 36 is a block for correcting imbalance between the I channel and the Q channel. The imbalance includes phase imbalance and amplitude imbalance. The phase imbalance is mainly caused by variations in the 90 degree phase section 24 of the receiver. The 90 degree phase section 24 cannot always generate two signal of which phases are exactly 90 degrees different from each other, and an angle or phase between the two signals are different from each other might vary due to fabrication variations, or temperature change, etc. The amplitude imbalance is mainly caused by a difference in performance between the VGA 261 in the I channel and the VGA 26Q in the Q channel. Even when the VGAs 26I and 26Q perform the same amplification operation, the amplitude of only one of the I channel signal and the Q channel signal might be slightly increased or reduced. The IMC section 36 detects such imbalance to correct the detected imbalance.

A symbol synchronization (SS) section (a digital arithmetic block) 37 is a block for performing symbol synchronization. In general, the transmitter and the receiver are separate apparatuses, and therefore, the BB oscillator 6 of the transmitter and the BB oscillator 29 of the receiver are not synchronized with each other. In this example, since oversampling is performed at the receiver, it is obvious that the BB oscillator 6 and the BB oscillator 29 are not synchronized with each other. Thus, a frequency difference and a phase difference exist. In other words, there is a difference between timings with which binary data (symbol) varies in the transmitter and sampling timings at the ADCs 30I and 30Q. In the SS section 37, this timing differences are detected and then are corrected. An interpolation filter configured of an FIR filter might be used to correct the timing differences.

A carrier offset correction (COC) section (a digital arithmetic block) 38 is a block for correcting an offset of a carrier. Since the transmitter and the receiver are separate apparatuses, output signals (carrier waves) of the RF oscillators 10 and 23 are not exactly matched with each other. Even when frequencies of the output signals are set to be 60 GHz, a frequency difference of about 3 MHz might be caused. Also, phases of the output signals are not matched with each other. Thus, the COC section 38 detects differences (offsets) in frequency and phase between carrier waves to correct the detected differences.

When adjustment and correction by the AGC/DCC 35, the IMC section 36, the SS section 37, and the COC section 38 are performed perfectly, an output of the COC section 38 is matched with an output of the I/Q mapping section 2 of the transmitter (see FIG. 2 and FIG. 4). However, in an actual case, the adjustment and correction are not performed perfectly, and thus, errors are generated.

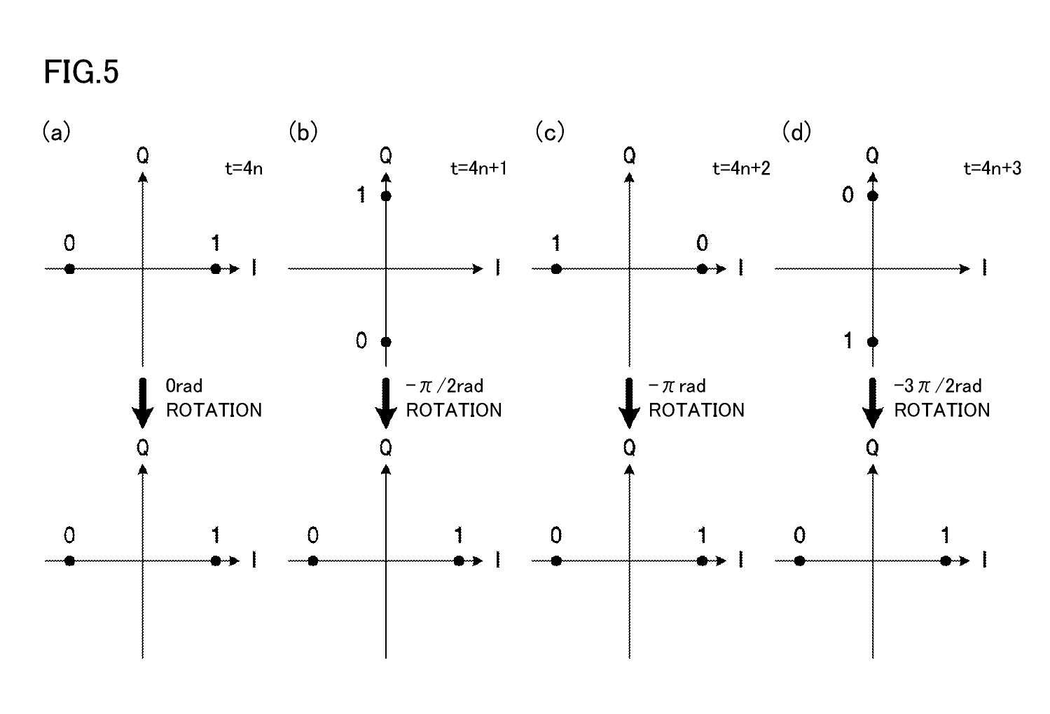

The I/Q demapping section 39 is a block for performing a reverse operation of the operation of the I/Q mapping section 2 of the transmission system of FIG. 2, and generates likelihood binary data from a signal point mapped on the I/Q plane. In π/2-BPSK modulation, rotation of π/2 per bit is not performed. As shown in FIGS. 5A-5D, it is ideal that signal points of the output of the I/Q demapping section 39 are concentrated at two points on an I-axis, but actually, the signal points are shifted from the two points. To show a shift amount, the outputs of the I/Q demapping section 39 are represented by soft values, not hard values of {−1, 1}. For example, if an output bit width is 4 bits, the output of the I/Q demapping section 39 can be represented using 16 values from −1 to 0.875 in increments of 0.125, i.e., −1, −0.875, −0.75, . . . , −0.125, 0, 0.125, . . . , 0.625, 0.75, 0.875.

The LDPC decoding section 40 is a block for performing error correction. Even when transmitted binary data is affected by noise, etc., and the data is incorrectly received, errors are corrected using redundancy provided beforehand, and the binary data matched with the transmitted binary data can be obtained by error correction of the LDPC decoding unit 40. In the LDPC decoding section 40, an input signal of the LDPC decoding section 40 is represented by soft values, and an output signal of the LDPC decoding section 40 is binary data.

Next, a method for calculating an indicator of channel quality according to this embodiment will be described.

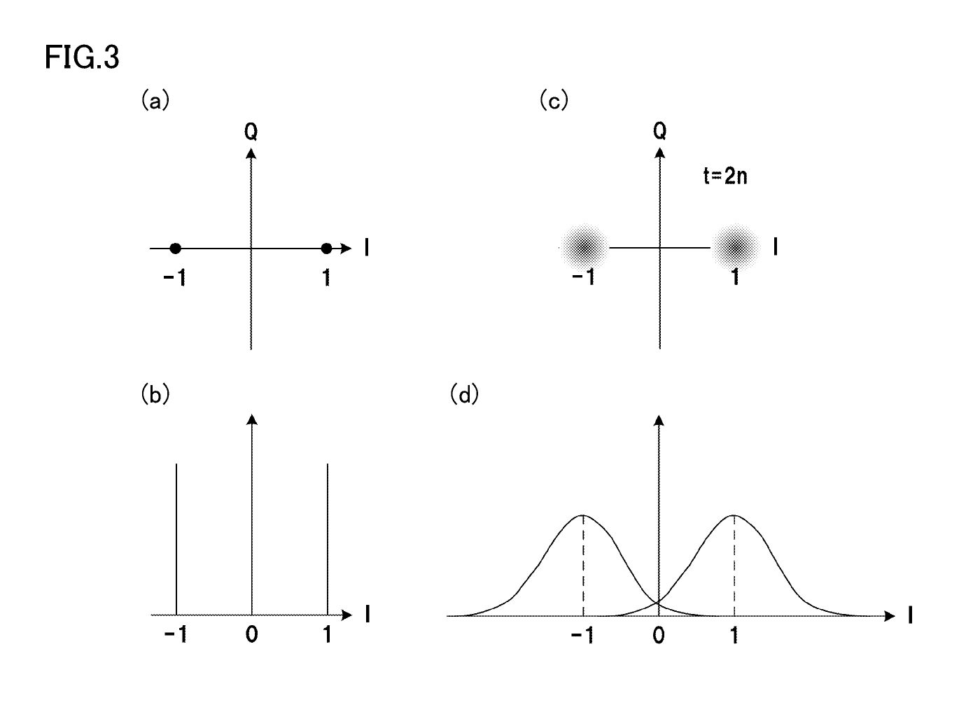

As shown in FIG. 3A, the signal points of the output of the I/Q demapping section 39 of the receiver of FIG. 1 are ideally concentrated at two points on the I-axis direction. The ideal signal points are represented by coordinates (1, 0) and (−1, 0). In a histogram format, as shown in FIG. 3B, the ideal signal points can be represented by two lines. However, actually, as shown in FIG. 3C, some signal points are located at other points than the two ideal points due to circuit variations in the transmitter, noise on a communication path, circuit variations of the receiver, and errors remaining after error correction in the receiver, etc. When a histogram is drawn up based on only values in the I-axis direction, ignoring values in a Q-axis, as shown in FIG. 3D, two bell-shaped curves appear.

When it is desired to obtain binary data directly from the signal point of the output of the I/Q demapping section 39, the value of the binary data may be determined based on only the value of the signal point in the I-axis direction. Specifically, if the value of the signal point is 0 or more, the binary data may be determined to be 1, and if the value of the signal point is less than 0, the binary value may be determined to be 0. That is, determination of the value of the binary data based on a threshold in which 0 is used as a threshold is performed. In this case, base portions of the bell-shaped curve of the histogram might become a problem. For example, in FIG. 3D, the bell-shaped curve at the positive-side has its left base portion located in an area of smaller than 0. If the histogram has a value in the area of smaller than 0, it is deemed that errors have occurred in determination of binary data. When the slope of the curve in the histogram is steep, determination errors are unlikely to occur. As the slope of the curve in the histogram becomes more gentle, the number of errors increases. When the channel quality is good, the slope of a bell-shaped curve is steep. As the channel quality is degraded, the slope of the bell-shaped curve becomes gentle. Mathematically, the steepness of a bell-shaped curve can be expressed as a variance. When the variation is obtained, a bit error rate (bER) can be obtained, and thus, the channel quality can be obtained.

The variance σ can be obtained based on the following equation, where the value of the signal point of the output of the I/Q demapping section 39 in the I-axis direction at a time j is xj.

$$σ = \frac{1}{N - 1} {\sum }_{j = 1}^{N} {( {x}_{j} - \overline{x} )}^{2} \\ ( \overline{x} is a mean value of x ) \qquad [ Equation 3 ]$$

Note that the above-described operation for calculating the variance may be replaced with an absolute value operation which is a more simple operation than a squaring operation.

This equation is an equation for calculating a channel quality indicator in this embodiment, and is an operation performed in a variance calculation section 45 of FIG. 1. Using the variance σ calculated by the variance calculation section 45, at least one of parameters of the BPF 21, the LNA 22, the RF oscillator 23, the 90 degree phase section 24, the LPFs 28I and 28Q, the ADCs 30I and 30Q, the AGC/DCC 35, the IMC section 36, the SS section 37, the COC section 38, and the I/Q demapping section 39 is controlled by a parameter control section 46.

In this embodiment, calculation of the variance σ by the variance calculation section 45 is performed based on the value of the signal point of the output of the I/Q demapping section 39 in the I-axis direction. However, the present disclosure is not limited thereto, but a variance of an intermediate signal of the demodulation section D, specifically, a variance of a signal in a subsequent stage of the ADCs 30I and 30Q may be calculated. The details of the above-described parameter control will be described later.

As described above, the LDPC decoding section 40 is a block for performing error correction. However, there is a limit to error correction ability of the LDPC decoding section 40. If an input signal to the LDPC decoding section 40 is good, the LDPC decoding section 40 can output binary data with no error, but if an input signal thereto is bad, the LDPC decoding section 40 cannot correct all errors, and outputs binary data with some remaining errors.

Although the limit of the error correction ability of the LDPC decoding section 40 varies greatly depending on coding efficiency, the limit value is assumed to be, for example, bER=10⁻³ in this case. The values of the input signal of the LDPC decoding section 40 are soft values. When bER obtained where the soft values are determined based on a threshold is better than 10⁻³, all of bit errors are corrected by the LDPC decoding section 40, and output with no error (bER=0) can be obtained. In contrast, when bER is worse than 10⁻³, errors remain. For example, when a bad input signal is given, i.e., for example, when bER=10⁻² is obtained as a result of the above-described determination based on a threshold, errors in an output are corrected only to the extent of bER=10⁻⁶. The foregoing shows that it is sufficient that the input signal is better, even slightly, than the error correction limit. In correction using the AGC/DCC 35, the IMC (I/Q imbalance correction) section 36, the SS (symbol synchronization) section 37, and the COC section 38, etc., even when bER for the input signal of the LDPC decoding unit 40 obtained as a result of the above-described determination based on a threshold is reduced to be as low as 10⁻⁴, an output of the LDPC decoding section 40 is not different at all from the output of the LDPC decoding section 40 when bER for the input is 10⁻³, and an output of bER=0 is obtained both when bER is 10⁻³ and when bER is 10⁻⁴.

As described above, there is a correlation between bER obtained when the input signal of the LDPC decoding section 40 is determined based on a threshold and the variance σ defined by the above-described operation. That is, whether or not bER is within the error correction limit of the LDPC decoding section 40 can be determined by checking the variance σ.

As an example, the histogram at the right hand side of FIG. 3D will be discussed. The ratio of an area of a region of less than 0 to an area of the entire histogram is bER. Assume that the histogram has a normal distribution. A mean value is 1. In this case, if the variance σ is 0.3236, bER=0.001. When σ>0.3236, bER>0.001, and when σ<0.3236, bER<0.001. That is, σ=0.3236 is an error correction limit. σ=0.3236 shown here is merely an example, and therefore, for the purpose of generalization, this value is referred to as a reference value of variance.

When the variance σ is calculated and the obtained value is much smaller than the reference value, it can be determined that the channel quality is significantly good. In this case, the gain of the LNA 22 is reviewed. If the gain of the LNA 22 is maximum, the gain is reduced by one level. Thus, the amplitude of the output signal of the LNA 22 is reduced, and the channel quality is degraded. Then, the variance σ is calculated again and the obtained value is compared to the reference value. If the obtained value is still smaller than the reference value, the gain of the LNA 22 is further reduced by one level. Then, the variance σ is obtained and the obtained value is compared to the reference value. As a result, if the obtained value is larger than the reference value, bER exceeds the error correction limit of the LDPC decoding section 40. Therefore, a certain margin is given to reduce the gain of the LNA 22 to a level with which the variance σ is slightly smaller than the reference value. When the gain of the LNA 22 is reduced in the above-described manner, the power consumption can be reduced, and the variance σ is smaller than the reference value, so that all of errors can be corrected by the LDPC decoding section 40. Thus, an optimal point for the channel quality and the power consumption in the LNA 22 can be found using the variance σ.

### Second Embodiment

Next, a second embodiment of the present disclosure will be described. According to this embodiment, the oscillation frequency of the BB oscillator 29 of the receiver is controlled using the variance σcalculated by the variance calculation section 45.

When the frequency of the BB oscillator 29 of the receiver is higher, the channel quality can be improved more greatly, but the power consumption is increased.

When the oscillation frequency is increased, the sampling number per unit time increases. That is, the time resolution is improved, and the symbol synchronization performance of the SS section 37 can be improved. That is, the channel quality can be improved.

However, the ADCs 30I and 30Q operate also at the oscillation frequency of the BB oscillator 29, and thus, when the frequency is doubled, the power consumption is also doubled.

Thus, to find an optimal point for the oscillation frequency of the BB oscillator 29, the channel quality, and the power consumption, the variance σ is used.

When the variance σ is calculated and the obtained value is much smaller than the reference value, it can be determined that the channel quality is significantly good. In this case, the oscillation frequency of the BB oscillator 29 is reviewed. If the oscillation frequency of the BB oscillator 29 is 7.04 GHz, i.e., 4 times oversampling frequency, the oscillation frequency is reduced to 3.52 GHz, i.e., double oversampling frequency. Thus, the time resolution is reduced, and the channel quality is degraded. Then, the variance σ is calculated again and the obtained value is compared to the reference value. If the obtained value is still smaller than the reference value, the oscillation frequency of the BB oscillator 29 is further reduced. For example, the oscillation frequency is reduced to 2.64 GHz, i.e., 1.5 times oversampling frequency. Then, the variance σ is calculated, and the obtained value is compared to the reference value. If the obtained value is larger than the reference value, bER exceeds the error correction limit of the LDPC decoding section 40. Therefore, a certain margin is given to reduce the oscillation frequency of the BB oscillator 29 to a level with which the variance σ is slightly smaller than the reference value. When the oscillation frequency of the BB oscillator 29 is reduced in the above-described manner, the power consumption can be reduced, and the variance σ is smaller than the reference value, so that all of errors can be corrected by the LDPC decoding section 40.

That is, an optimal point for the oscillation frequency of the BB oscillator 29, the channel quality, and the power consumption can be found using the variance σ.

### Third Embodiment

Furthermore, a third embodiment of the present disclosure will be described. According to this embodiment, resolutions of the ADCs 30I and 30Q of the receiver are controlled using the variance σ calculated by the variance calculation section 45.

A quantization error in a direction of amplitude can be reduced by increasing the resolutions of the ADCs 30I and 30Q, i.e., bit widths of outputs of the ADCs 30I and 30Q. That is, the channel quality can be improved. However, as the ADC resolution increases, the power consumption increases.

Thus, to find an optimal point for the resolutions of the ADCs 30I and 30Q, the channel quality, and the power consumption, the variance σ is used.

When the variance σ is calculated and the obtained value is much smaller than the reference value, it can be determined that the channel quality is significantly good. In this case, the resolutions of the ADCs 30I and 30Q are reviewed. If the ADC resolution is 4 bits or 16 gradations, the ADC resolution is reduced to 3 bits or 8 gradations. Thus, the quantization error is increased, and therefore, the channel quality is degraded. Then, the variance σ is calculated again, and the obtained value is compared to the reference value. If the obtained value is still smaller than the reference value, the ADC resolution is further reduced. For example, the ADC resolution is reduced to 2 bits or 4 gradations. Then, the variance σ is calculated, and the obtained value is compared to the reference value. If the obtained value is larger than the reference value, bER exceeds the error correction limit of the LDPC decoding section 40. Therefore, a certain margin is given to reduce the ADC resolution to a level with which the variance σ is slightly smaller than the reference value. When the resolutions of the ADCs 30I and 30Q are reduced in the above-described manner, the power consumption can be reduced, and the variance σ is smaller than the reference value, so that all of errors can be corrected by the LDPC decoding section 40.

That is, an optimal point for the resolutions of the ADCs 30I and 30Q, the channel quality, and the power consumption can be found using the variance σ.

### Fourth Embodiment

Subsequently, a fourth embodiment of the present disclosure will be described. According to this embodiment, the operation accuracy of the digital blocks such as the IMC section 36, the SS section 37, and the COC section 38, etc., is controlled using the variance σ calculated by the variance calculation section 45.

When the operation accuracy of the digital blocks such as the IMC section 36, the SS section 37, and the COC section 38, etc., of FIG. 1 is increased, the channel quality can be improved, but the power consumption is increased.

For example, when an interpolation filter of the SS section 37 is composed of a FIR filter, the number of taps of the filter, and the bit width of the tap coefficient are increased, the operation accuracy increases, and more accurate symbol synchronization can be performed, so that the channel quality is improved. However, when the number of taps, or the coefficient bit width is increased, the operation amount increases, thus resulting in increase in power consumption.

Thus, to find an optimal point for the operation accuracy of the SS section 37, the channel quality, and the power consumption, the variance σ is used.

When the variance σ is calculated and the obtained value is much smaller than the reference value, it can be determined that the channel quality is significantly good. In this case, the operation accuracy of the interpolation filter of the SS section 37 is reviewed. If the number of taps of the interpolation filter is 6, the number of taps is reduced to 4. Thus, the interpolation accuracy is reduced, and thus, the channel quality is degraded. Then, the variance σ is calculated again, and the obtained value is compared to the reference value. If the obtained value is still smaller than the reference value, the number of taps is further reduced. For example, the number of taps is reduced to 2 to obtain a simple, linear interpolation filter. Then, the variance σ is obtained again, and the obtained value is compared to the reference value. If the obtained value is larger than the reference value, bER exceeds the error correction limit of the LDPC decoding section 40. Therefore, a certain margin is given to reduce the number of taps to a number with which the variance σ is slightly smaller than the reference value. When the number of taps of the interpolation filter of the SS section 37 is reduced in the above-described manner, the power consumption can be reduced, and the variance σ is smaller than the reference value, so that all of errors can be corrected by the LDPC decoding section 40.

Accordingly, an optimal point for the operation accuracy of the digital arithmetic blocks such as the IMC section 36, the SS section 37, and the COC section 38, etc., the channel quality, and the power consumption can be found using the variance σ.

In the above-described embodiments, the examples in which parameters such as the gain of the LNA 22, the oscillation frequency of the BB oscillator 29, the resolutions of the ADCs 30I and 30Q, the operation accuracy of the digital arithmetic blocks 35-38, etc., are optimized using the variance σ have been described. However, in addition to the above-described parameters, there are other parameters which can be controlled using the indicator σ. Examples of such parameters are shown below.

BPF: bandpass characteristics (passes in any band, a wide band, or a narrow band)

LNA: the gain

RF oscillator: the amount of reduction of jitter

90 degree phase section: the amount of correction of phase imbalance

LPF: passes in any band, a wide band, or a narrow band

BB oscillator: the oscillation frequency

ADC: the resolution (bit number)

AGC/DCC: frequency of controlling

I/Q imbalance correction: presence/absence of correction at any time, the operation accuracy (internal operation bit width)

Symbol synchronization: presence/absence of correction at any time, the operation accuracy (internal operation bit width)

Carrier offset correction: presence/absence of correction at any time, the operation accuracy (internal computation bit width)

### Fifth Embodiment

Next, a fifth embodiment of the present disclosure will be described. This embodiment relates to a transmission/reception system including the receiver of FIG. 1 and the transmitter of FIG. 2.

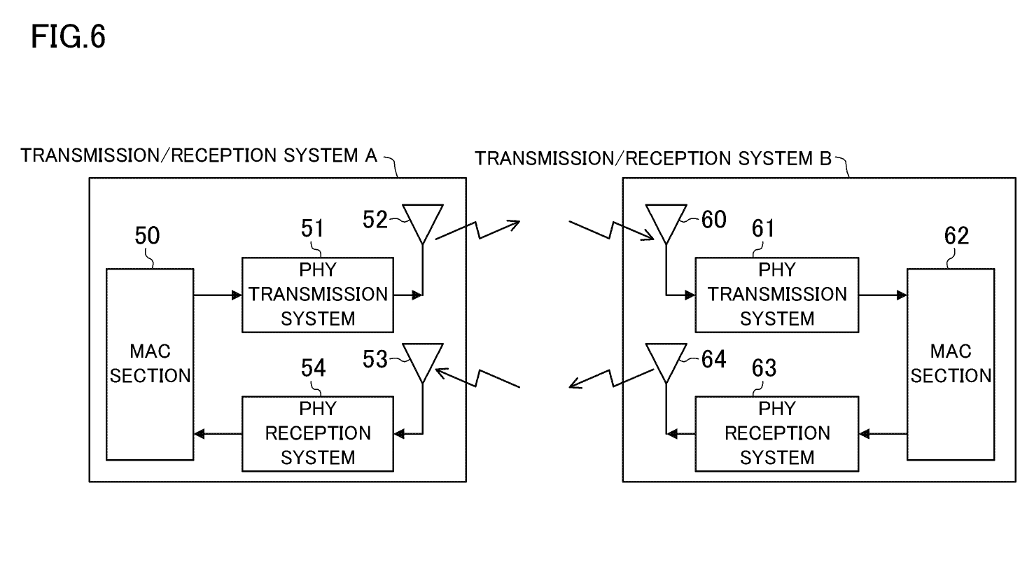

The transmission/reception system of this embodiment is shown in FIG. 6.

In FIG. 6, for example, binary data is drawn up in a media access control (MAC) section 50 of a transmission/reception system A such as a cellular phone, etc., the drawn binary data is modulated by a PHY transmitting system 51, and a radio wave is sent from a transmission antenna 52.

For example, the radio wave is received by a reception antenna 60 of a transmission/reception system B such as a stationary videocassette recorder, and the received radio wave is demodulated by a PHY receiving system 61 including the receiver of FIG. 1. Simultaneously with the demodulation, the indicator σ is calculated by a variance calculation section in the PHY receiving system 61. The calculated indicator σ is output to a PHY transmitting system 63 via a MAC section 62 and is modulated in the PHY transmitting system 63, and the modulated indicator σ is sent as a radio wave by a transmission antenna 64.

In the transmission/reception system A, a reception antenna 53 receives the radio wave output from the transmission/reception system B, and the received radio wave is demodulated by the PHY transmitting system 54. In the MAC section 50, the received indicator σ is interpreted, and if the indicator σ is small, the gain of a transmission amplifier (not shown) provided in a previous stage of the transmission antenna 52 is reduced to lower transmission power.

Thus, according to this embodiment, in the transmission/reception system A which has received the indicator σ from the transmission/reception system B, transmission power is also controlled based on the received indicator σ. Thus, the power consumption of the transmission/reception system A can be reduced.

As described above, according to the present disclosure, the variance σ which is a compact indicator having a strong correlation with bER and does not require, as opposed to a conventional indicator MER, division or logarithmic operation is used as an indicator for signal quality to finely control various blocks of a receiver and a transmission/reception system so that the indicator σ is small. Thus, the performance and power consumption of the receiver and the transmission/reception system can be optimized. Therefore, the present disclosure is useful for receivers and transmission/reception systems.

What is claimed is:

1. A receiver which includes a demodulation section configured to demodulate a received signal, comprising:
a variance calculation section configured to calculate a variance of an intermediate output signal of the demodulation section as an indicator for signal quality.

2. The receiver of claim 1, wherein
the demodulation section includes an analog/digital converter, and
the variance calculation section calculates a variance of a signal in a subsequent stage of the analog/digital converter.

3. The receiver of claim 1, wherein
the variance calculation section calculates the variance a based on an equation:
$$σ = \frac{1}{N - 1} {\sum }_{j = 1}^{N} {( {x}_{j} - \overline{x} )}^{2} \\ ( \overline{x} is a mean value of x ) \qquad [ Equation 4 ]$$
where a value of a signal at a time j is xj.

4. The receiver of claim 1, further comprising:
a parameter control section configured to receive the variance calculated by the variance calculation section and control a parameter of a block provided in the demodulation section so that a value of the variance is small.

5. The receiver of claim 4, wherein
the block provided in the demodulation section is a low-noise amplifier configured to amplify the received signal, and
the parameter control section controls a gain of the low-noise amplifier.

6. The receiver of claim 4, wherein
the block provided in the demodulation section is a baseband oscillator, and
the parameter control section controls an oscillation frequency of the baseband oscillator.

7. The receiver of claim 4, wherein
the block provided in the demodulation section is an analog/digital converter, and
the parameter control section controls an output bit width of the analog/digital converter.

8. The receiver of claim 4, wherein
the block provided in the demodulation section is a digital arithmetic block, and
the parameter control section controls operation accuracy of the digital arithmetic block.

9. The receiver of claim 4, wherein
the block provided in the demodulation section includes a bandpass filter, a RF oscillator, an automatic gain controller, a DC offset canceller, a symbol synchronizer, or a carrier offset corrector.

10. The receiver of claim 4, wherein
the received signal includes binary data mapped on an I/Q plane, and
the block provided in the demodulation section includes a 90 degree phase section or an IQ imbalance corrector.

11. The receiver of claim 4, wherein
in the demodulation section, an error correction block is provided,
the parameter control section controls the parameter of the block provided in the demodulation section so that the variance calculated by the variance calculation section is close to a value corresponding to an error correction limit of the error correction block.

12. A transmission/reception system, comprising:
the receiver of claim 1; and
a transmitter configured to transmit a transmission signal to the receiver.

13. The transmission/reception system of claim 12, wherein
the receiver transmits the variance calculated by the variance calculation section to the transmitter, and
the transmitter controls transmission power of the transmission signal based on the variance transmitted from the receiver.

14. The transmission/reception system of claim 12, wherein
the transmission signal is a signal in a millimeter wave band.
